(19) United States
(12) Patent Application Publication
(10) Pub. No.: US 2025/0194030 A1
(43) Pub. Date: Jun. 12, 2025

(54) FOLDABLE ELECTRONIC DEVICE

(71) Applicant: SYNCMOLD ENTERPRISE CORP., New Taipei City (TW)

(72) Inventors: Ching-Hui Yen, New Taipei City (TW); Chien-Cheng Yeh, New Taipei City (TW); Chun-Hao Huang, New Taipei City (TW)

(21) Appl. No.: 18/918,155

(22) Filed: Oct. 17, 2024

Related U.S. Application Data
(60) Provisional application No. 63/607,236, filed on Dec. 7, 2023.

(30) Foreign Application Priority Data
Jul. 30, 2024 (TW) 113128388

(51) Int. Cl. H05K 5/02

(52) U.S. Cl. CPC H05K 5/0226

(57) ABSTRACT

A foldable electronic device is provided and comprises a shell member, at least two pivoting modules and a wire. The shell member includes at least two base portions and a limiting portion. The limiting portion is located between the base portions. The pivoting modules are disposed on the base portions respectively. The wire is sandwiched between the pivoting modules and the shell member and includes at least one through hole. The limiting portion penetrates through the through hole. The wire is able to move integrally in any direction relative to the limiting portion.

### CROSS-REFERENCE TO RELATED APPLICATION

This application claims the benefit of U.S. Provisional Application Ser. No. 63/607,236 filed on Dec. 7, 2023, and the benefit of Taiwan Patent Application Serial No. 113128388 filed on Jul. 30, 2024. The entirety of each Application is incorporated herein by reference.

### BACKGROUND

### 1. Technical Field

The present disclosure relates to a foldable electronic device, and more particularly, to a foldable electronic device capable of preventing a wire from being torn.

### 2. Description of Related Art

Flexible screens have been widely used in smartphones and tablets, such as foldable electronic devices. The foldable electronic device includes a housing, a folding mechanism mounted on the housing, and a flexible screen provided on the folding mechanism. For the power/signal transmission of the flexible screen, a wire electrically connected to the flexible screen is provided between the housing and the folding mechanism, and the wire is fixed to the housing via an adhesive to avoid displacement. However, when the foldable electronic device is unfolded or folded, the wire may be easily torn due to stretching or squeezing.

### SUMMARY

The present disclosure provides a foldable electronic device, which comprises: a shell member extending along a first direction and including at least two base portions and a limiting portion, wherein the limiting portion is located between the base portions and extends along a second direction substantially perpendicular to the first direction; at least two pivoting modules disposed on the base portions respectively; and a wire substantially extending along a third direction perpendicular to the first direction and the second direction and sandwiched between the pivoting modules and the shell member, wherein the wire includes at least one through hole, and the limiting portion penetrates through the through hole, wherein the pivoting modules are able to transform between an unfolded state and a folded state, wherein when the pivoting modules are transformed between the unfolded state and the folded state and the wire is not being limited by at least one of the limiting portion, the shell member and the pivoting modules, the wire is able to move integrally in any direction relative to the limiting portion.

In the aforementioned foldable electronic device, the wire further includes a wire body and a positioning portion protruding from one side of the wire body along the first direction, and the through hole substantially penetrates through the positioning portion along the second direction.

In the aforementioned foldable electronic device, the limiting portion has at least one positioning post extending substantially along the second direction, the through hole is sleeved on the positioning post, and the wire is able to move radially or axially relative to the positioning post.

In the aforementioned foldable electronic device, the limiting portion further has a placement surface adjacent to the positioning post, and the wire body is correspondingly disposed on the placement surface.

In the aforementioned foldable electronic device, a cross-sectional area of the through hole is greater than a cross-sectional area of the positioning post.

In the aforementioned foldable electronic device, the wire body is a flat wire or a round wire.

In the aforementioned foldable electronic device, the positioning portion is a tape or a printed circuit board disposed on the wire body.

In the aforementioned foldable electronic device, a cross-section of the through hole is circular.

In the aforementioned foldable electronic device, each of the pivoting modules includes a central base, two wing members, two transmission members, two panel bodies, two drop plates, a torque module and a synchronization module, wherein the central base is fixed to the base portion, the wing members are pivotally connected to the central base, the transmission members are connected to the central base and the torque module, the panel bodies are connected to the wing members and the transmission members, the drop plates are connected to the wing members and the panel bodies, the torque module is provided on the central base, and the synchronization module is slidably provided between the transmission members.

The aforementioned foldable electronic device further comprises a flexible screen electrically connected to the wire and disposed on the wing members, the panel bodies and the drop plates, wherein the flexible screen is flattened in the unfolded state and is bent in the folded state.

In the aforementioned foldable electronic device, the shell member further includes a shell body having a first notch and a second notch corresponding to the first notch, wherein the wire penetrates through the first notch and the second notch.

As can be understood from the above, when the foldable electronic device of the present disclosure is transformed between the unfolded state and the folded state, the wire can be moved integrally in any direction relative to the limiting portion, so the wire can be prevented from being damaged or torn due to stretching or squeezing during the folding process.

### BRIEF DESCRIPTION OF THE DRAWINGS

FIG. 1 is an overall schematic view of a foldable electronic device of the present disclosure.

FIG. 2 is an exploded schematic view of the foldable electronic device of the present disclosure.

FIG. 3 is an exploded schematic view of a pivoting module of the foldable electronic device of the present disclosure.

FIG. 4 is a schematic cross-sectional view of the foldable electronic device of the present disclosure in an unfolded state.

FIG. 5 is a schematic cross-sectional view of a wire in FIG. 4 after being moved.

FIG. 6 is a schematic cross-sectional view of the foldable electronic device of the present disclosure in a folded state.

### DETAILED DESCRIPTION

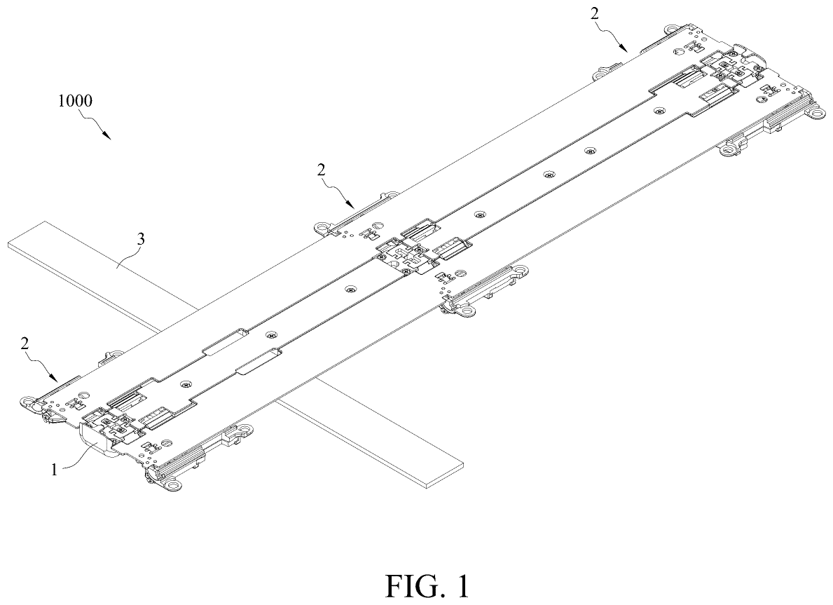

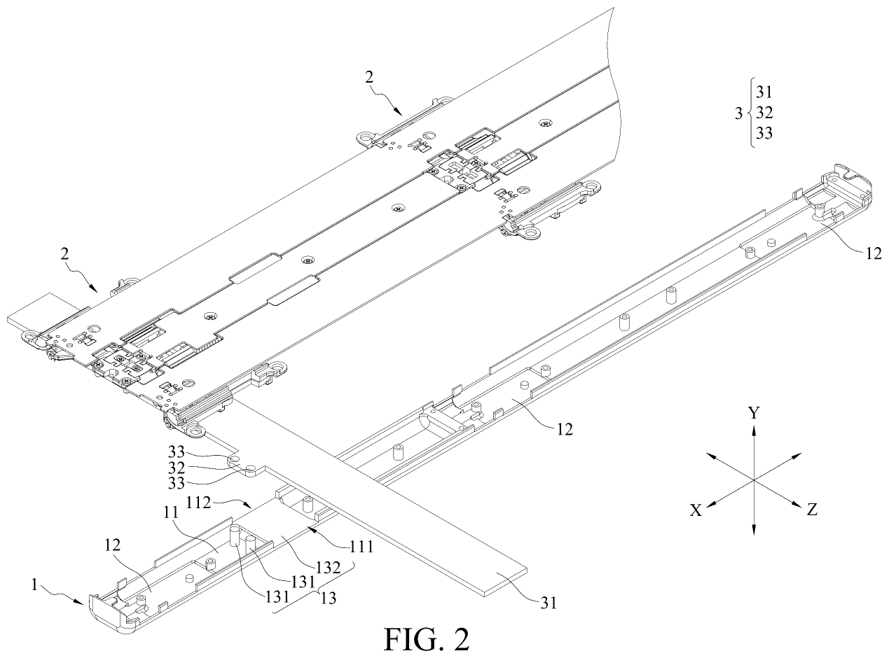

Referring to FIG. 1 and FIG. 2, a foldable electronic device 1000 of the present disclosure comprises a shell member 1, three pivoting modules 2 and a wire 3. The shell member 1 and the pivoting modules 2 are combined with each other, and the wire 3 is sandwiched between the shell member 1 and the pivoting modules 2. The structure of each element and the connection relationship between the elements will be described in detail below, while some of the figures are drawn with a first direction X, a second direction Y and a third direction Z that are perpendicular to each other.

The shell member 1 includes a shell body 11, three base portions 12 and a limiting portion 13. The shell body 11 extends along the first direction X and is a long shell with a U-shaped cross-section, and opposite sides of the shell body 11 are provided with a first notch 111 and a second notch 112 corresponding to the first notch 111. The base portions 12 are formed on the shell body 11 and spaced apart from each other, and two of the base portions 12 are respectively located at the opposite ends of the shell body 11, while the remaining base portion 12 is roughly located in the middle of the shell body 11. The limiting portion 13 is adjacent to one of the base portions 12 and has two positioning posts 131 and a placement surface 132. The positioning posts 131 are generally in the shape of a cylinder and extend outward from the shell body 11 along the second direction Y at intervals. The placement surface 132 is adjacent to the positioning posts 131 and extend along the first direction X and the third direction Z, and the placement surface 132 is facing the pivoting modules 2 and located between the first notch 111 and the second notch 112 in the third direction Z.

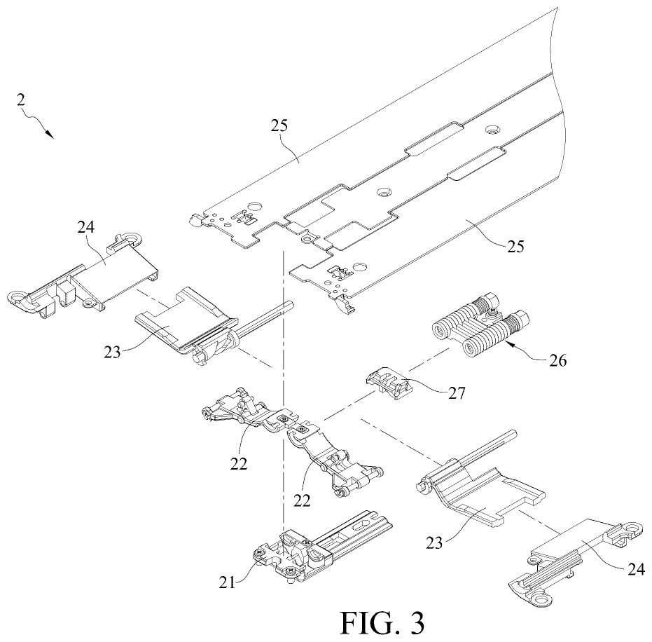

Referring to FIG. 3, the pivoting module 2 includes a central base 21, two wing members 22, two transmission members 23, two panel bodies 24, two drop plates 25, a torque module 26 and a synchronization module 27. The central base 21 is locked to the base portion 12 via, for example, screws. The wing members 22 are pivotally connected to opposite sides of the central base 21. The transmission members 23 connect the central base 21 and the torque module 26. The panel bodies 24 are pivotally connected to the wing members 22 respectively and connected to the transmission members 23 respectively. The drop plates 25 are connected to the wing members 22 and the panel bodies 24 respectively. The torque module 26 is disposed on the shell body 11 and adjacent to the limiting portion 13. The synchronization module 27 is slidably connected between the transmission members 23. The two drop plates 25 can be shared by a plurality of pivoting modules 2 simultaneously, or can be used by a single pivoting module 2. That is, the three pivoting modules 2 can cooperate with six drop plates 25, but the present disclosure is not limited to as such.

The wire 3 is sandwiched between the pivoting modules 2 and the shell member 1, and includes a wire body 31, a positioning portion 32 and two through holes 33. The wire body 31 is generally strip-shaped and substantially extending along the third direction Z, and is correspondingly disposed on the placement surface 132 and penetrating through the first notch 111 and the second notch 112. The wire body 31 may be a flat wire or a round wire, and a width thereof along the first direction X is less than the size of the first notch 111 and the second notch 112, but is not limited thereto. The positioning portion 32 is roughly in the shape of a rectangular parallelepiped with rounded corners, is protruded from one side of the wire body 31 along the first direction X, and is located inside the shell member 1. The positioning portion 32 can be a piece of tape or a printed circuit board (PCB), but is not limited thereto. The through holes 33 substantially penetrate through the positioning portion 32 along the second direction Y, and are respectively sleeved on the positioning posts 131. In this embodiment, the cross-section of each of the through holes 33 is circular, and the cross-sectional area of each of the through holes 33 is greater than or equal to the cross-sectional area of each of the positioning posts 131, whereby the wire 3 can be moved radially relative to the positioning posts 131.

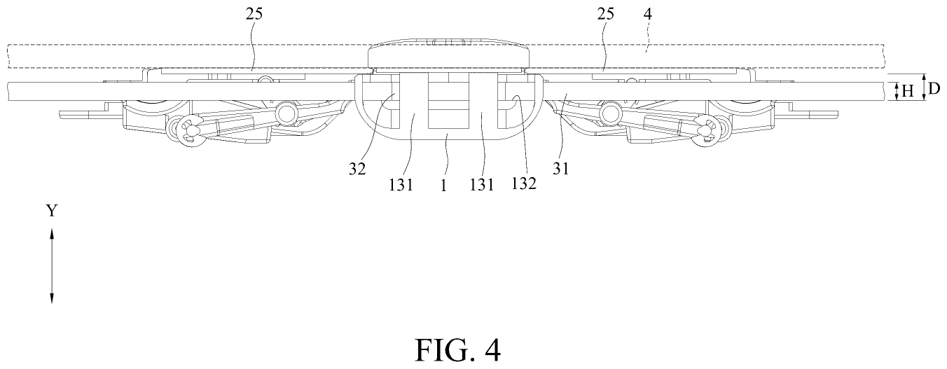

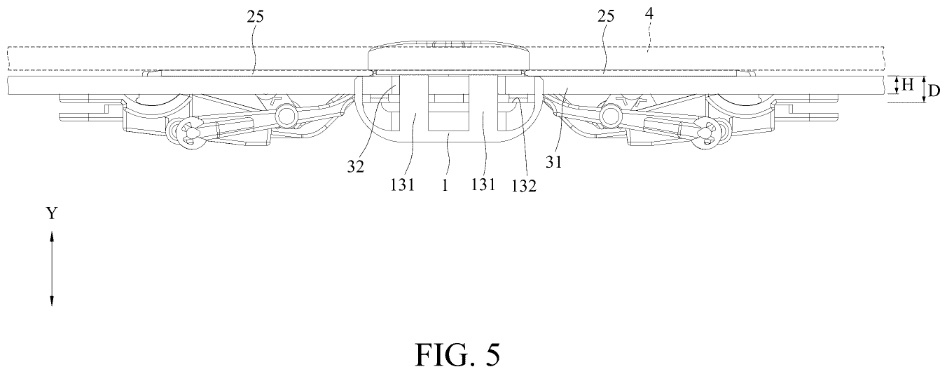

Referring to FIG. 4 and FIG. 5 at the same time, the wire body 31 has a thickness H in the second direction Y. The thickness H is less than a distance D between the pivoting modules 2 and the shell member 1. Therefore, the wire body 31 can be moved axially (that is, along the second direction Y) relative to the positioning posts 131. For example, the wire body 31 can be moved between a position attached to the placement surface 132 (FIG. 4) and a position attached to the drop plates 25 (FIG. 5).

The distance D between the pivoting modules 2 and the shell member 1 can be used as the maximum overall displacement of the wire 3 in the second direction Y. The maximum overall displacement is less than 10 mm, but the present disclosure is not limited to as such. Alternatively, the maximum overall displacement of the wire 3 in the first direction X or the third direction Z can be determined by the clearance fit between the through holes 33 and the positioning posts 131 (e.g. greater than 0 mm, less than 10 mm), or by the clearance fit between the wire body 31 and the first notch 111 and the second notch 112 (e.g. greater than 0 mm, less than 10 mm).

The above description takes two positioning posts 131 and two through holes 33 as an example, but the present disclosure is not limited to as such. It can also be a combination of a single positioning post 131 and a single through hole 33.

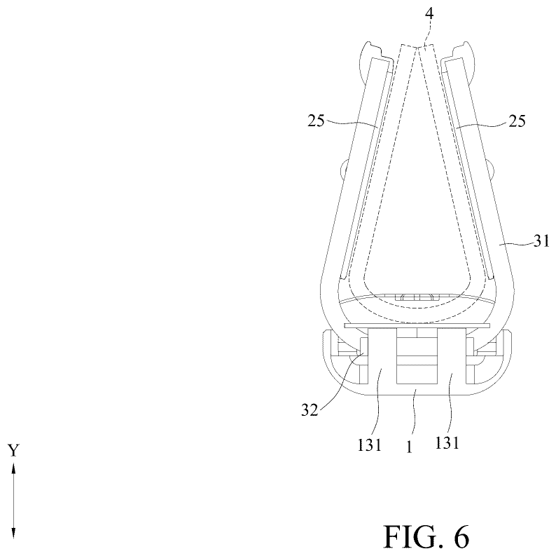

A flexible screen 4 is electrically connected to the wire 3 and is disposed on the wing members 22, the panel bodies 24 and the drop plates 25. Referring to FIG. 6, the pivoting modules 2 in the foldable electronic device 1000 of the present disclosure can be transformed between an unfolded state (FIG. 4 and FIG. 5) and a folded state (FIG. 6). When in the unfolded state, the flexible screen 4 is flattened. When in the folded state, the flexible screen 4 is bent. When the pivoting modules 2 transform between the unfolded state and the folded state, the through holes 33 are not limited by the positioning posts 131 (for example, the first direction X and the third direction Z), the wire body 31 is not limited by the first notch 111 and the second notch 112 of the shell body 11 (for example, the first direction X and the third direction Z), or the wire body 31 is not limited by the placement surface 132 and the pivoting module 2 (for example, the second direction Y), the wire 3 can be moved integrally in any direction relative to the limiting portion 13 (i.e., axially, radially, or obliquely).

In view of the above, when the foldable electronic device of the present disclosure is transformed between the unfolded state and the folded state, the wire can be moved integrally in any direction relative to the limiting portion, so the wire can be prevented from being damaged or torn due to stretching or squeezing during the folding process.

What is claimed is:

1. A foldable electronic device, comprising:
a shell member extending along a first direction and including at least two base portions and a limiting portion, wherein the limiting portion is located between the base portions and extends along a second direction substantially perpendicular to the first direction;
at least two pivoting modules disposed on the base portions respectively; and
a wire substantially extending along a third direction perpendicular to the first direction and the second direction and sandwiched between the pivoting modules and the shell member, wherein the wire includes at least one through hole, and the limiting portion penetrates through the through hole,
wherein the pivoting modules are able to transform between an unfolded state and a folded state, wherein when the pivoting modules are transformed between the unfolded state and the folded state and the wire is not being limited by at least one of the limiting portion, the shell member and the pivoting modules, the wire is able to move integrally in any direction relative to the limiting portion.

2. The foldable electronic device of claim 1, wherein the wire further includes a wire body and a positioning portion protruding from one side of the wire body along the first direction, and the through hole substantially penetrates through the positioning portion along the second direction.

3. The foldable electronic device of claim 2, wherein the limiting portion has at least one positioning post extending substantially along the second direction, the through hole is sleeved on the positioning post, and the wire is able to move radially or axially relative to the positioning post.

4. The foldable electronic device of claim 3, wherein the limiting portion further has a placement surface adjacent to the positioning post, and the wire body is correspondingly disposed on the placement surface.

5. The foldable electronic device of claim 4, wherein a cross-sectional area of the through hole is greater than a cross-sectional area of the positioning post.

6. The foldable electronic device of claim 5, wherein the wire body is a flat wire or a round wire.

7. The foldable electronic device of claim 6, wherein the positioning portion is a tape or a printed circuit board disposed on the wire body.

8. The foldable electronic device of claim 7, wherein a cross-section of the through hole is circular.

9. The foldable electronic device of claim 1, wherein each of the pivoting modules includes a central base, two wing members, two transmission members, two panel bodies, two drop plates, a torque module and a synchronization module, wherein the central base is fixed to the base portion, the wing members are pivotally connected to the central base, the transmission members are connected to the central base and the torque module, the panel bodies are connected to the wing members and the transmission members, the drop plates are connected to the wing members and the panel bodies, the torque module is provided on the central base, and the synchronization module is slidably disposed between the transmission members.

10. The foldable electronic device of claim 9, further comprising a flexible screen electrically connected to the wire and disposed on the wing members, the panel bodies and the drop plates, wherein the flexible screen is flattened in the unfolded state and is bent in the folded state.

11. The foldable electronic device of claim 9, wherein the shell member further includes a shell body having a first notch and a second notch corresponding to the first notch, wherein the wire penetrates through the first notch and the second notch.
